(19) United States
(12) Patent Application Publication
(10) Pub. No.: US 2023/0422405 A1
(43) Pub. Date: Dec. 28, 2023

(54) CIRCUIT STRUCTURE FOR HOT-PRESS BONDING

(71) Applicant: SUPERC-TOUCH CORPORATION, New Taipei City (TW)

(72) Inventors: Hsiang-Yu LEE, New Taipei City (TW); Shang CHIN, New Taipei City (TW); Ping-Tsun LIN, New Taipei City (TW)

(21) Appl. No.: 18/318,267

(22) Filed: May 16, 2023

(30) Foreign Application Priority Data
Jun. 23, 2022 (TW) 111123472

(51) Int. Cl. H05K 3/32; H05K 1/02

(52) U.S. Cl. CPC H05K 3/323; H05K 1/0278; H05K 1/028; H05K 2201/023; H05K 2201/0335; H05K 2201/095; H05K 2203/068

(57) ABSTRACT

A circuit structure for hot-press bonding includes a first substrate, a second substrate and a conductive adhesive layer. The circuit structure further includes a first conductive layer having a plurality of connection electrodes arranged on the first substrate, a second conductive layer including a plurality of backup electrodes respectively corresponding to the connection electrodes, an insulating layer arranged between the first conductive layer and the second conductive layer, and a plurality of conductive via arranged in the insulating layer and connected to corresponding connection electrodes and backup electrodes to provide current conduction paths therebetween, thus provide additional conduction path for the connection electrodes even the connection electrodes have fracture and enhance yield and connection reliability.

### BACKGROUND OF THE INVENTION

### Technical Field

The present invention relates to a circuit structure, especially to a circuit structure for hot-press bonding.

### Description of Related Art

As the electronic products are developed to integrate more functional components, the connection between circuit boards is also developing rapidly. For example, the connection mechanism between the FPC flexible board and the PCB has applications for various kinds of electronic products, especially wearable devices and thin, lightweight and compact handheld electronic devices. Besides, as another example, the interconnection between the electrodes of the display screen and the flexible circuit board, the interconnection between the flexible circuit board and the rigid circuit board, and the interconnection between flexible circuit boards are important considerations when manufacturing display devices or touch-input display devices. For achieving interconnection between circuit boards, anisotropic conductive film (ACF) adhesives are applied between the components to be connected (such as electrodes). Afterward, the ACF adhesives are pressed and heated to provide reliable mechanical and electrical connection between the electrodes. The above process can be referred to as hot-press welding or hot-press bonding.

Anisotropic conductive film (ACF) adhesive achieves electrical connection by the small conductive particles filled therein. The electrical conductivity of ACF adhesive increases with increased filing rate of the small conductive particles. The ordinary particle size range is between 3 μm and 8 μm. The excessively large conductive particles decrease the number of the conductive particles for contacting each electrode and tend to short circuit due to the physical contact between adjacent conductive particles. The excessively small conductive particles form particle aggregation easily to cause non-uniform distribution density

However, the hot-press bonding between components/circuit boards or circuit boards/circuit boards in the related-art may cause fracture of the wires in the components/circuit boards and the product yield is affected.

### SUMMARY OF THE INVENTION

It is an object of the present invention to provide a circuit structure for hot-press bonding. The circuit structure has backup connection path for connection electrodes such that the connection path can be prevented from disconnection even though the connection electrode has fracture. Therefore, the reliability for electric connection and the processing yield are enhanced.

Accordingly, the present invention provides a circuit structure for hot-press bonding, which comprising:

a first substrate;

a first conductive layer comprising a plurality of connection electrodes, the plurality of connection electrodes arranged in rows and arranged on a planar surface of the first substrate;

a second conductive layer comprising a plurality of backup electrodes, each of the backup electrodes corresponding to one of the connection electrodes of the first conductive layer;

an insulating layer arranged between the first conductive layer and the second conductive layer;

a plurality of conductive vias arranged in the insulating layer; wherein multiple of the conductive vias are provided between each of the backup electrodes and a corresponding one of the connection electrode such that multiple of the conductive vias provide current conduction paths between each of the backup electrodes and the corresponding one of the connection electrodes;

a second substrate;

a plurality of conductive pads arranged in a row and arranged on a planar surface of the second substrate, each of the conductive pads being corresponding to one of the connecting electrodes of the first substrate; and

a conductive adhesive layer arranged between the plurality of connection electrodes of the first substrate and the plurality of conductive pads of the second substrate such that each of the connection electrodes is electrically connected to a corresponding one of the conductive pads.

According to one aspect of the present invention, the first substrate is, for example, a rigid substrate, such as a glass substrate; or a flexible substrate, such as a PI (Polyimide) substrate. The second substrate is, for example, a flexible polymer substrate.

According to another one aspect of the present invention, the first conductive layer is, for example, a transparent conductive layer, such as an ITO (indium tin oxide) layer. Alternatively, the first conductive layer is, for example, a metal conductive layer, and the metal can be copper, aluminum, molybdenum, or silver.

According to another one aspect of the present invention, the second conductive layer is, for example, a metal conductive layer, and the metal is, for example, copper, aluminum, molybdenum, or silver.

According to another one aspect of the present invention, the circuit structure further comprises a transparent conductive layer arranged on the first conductive layer, wherein the transparent conductive layer comprises a plurality of transparent connection electrodes, each of the transparent connection electrodes is corresponding and electrically connected to one of the connecting electrodes of the first conductive layer.

According to another one aspect of the present invention, the conductive vias are arranged along two long sides of each of the connecting electrodes. An extended length of the conductive vias is more than 70% of a length of the connecting electrode, and the separation between two adjacent conductive vias is not greater than twice a diameter of the conductive vias.

### BRIEF DESCRIPTION OF THE DRAWINGS

The features of the invention believed to be novel are set forth with particularity in the appended claims. The invention itself, however, may be best understood by reference to the following detailed description of the invention, which describes a number of exemplary embodiments of the invention, taken in conjunction with the accompanying drawings, in which:

FIG. 1A shows a side view of the circuit structure according to a comparative example of the present invention.

FIG. 1B shows another side view of the circuit structure according to a comparative example of the present invention.

FIGS. 1C and 1D are partially enlarged views for showing more detail after the substrates shown in FIG. 1B are pressed.

FIG. 2 shows a side view of a circuit structure for hot-press bonding according to an embodiment of the present invention.

FIG. 3A shows a partial side view of the circuit structure for hot-press bonding according to an embodiment of the present invention.

FIG. 3B shows a top view corresponding to FIG. 3A.

FIG. 4A shows a side view of a circuit structure for hot-press bonding according to another embodiment of the present invention.

FIG. 4B shows a partial side view of a circuit structure for hot-press bonding according to another embodiment of the present invention.

### DETAILED DESCRIPTION OF THE INVENTION

The technical contents of this invention will become apparent with the detailed description of embodiments accompanied with the illustration of related drawings as follows. It is intended that the embodiments and drawings disclosed herein are to be considered illustrative rather than restrictive.

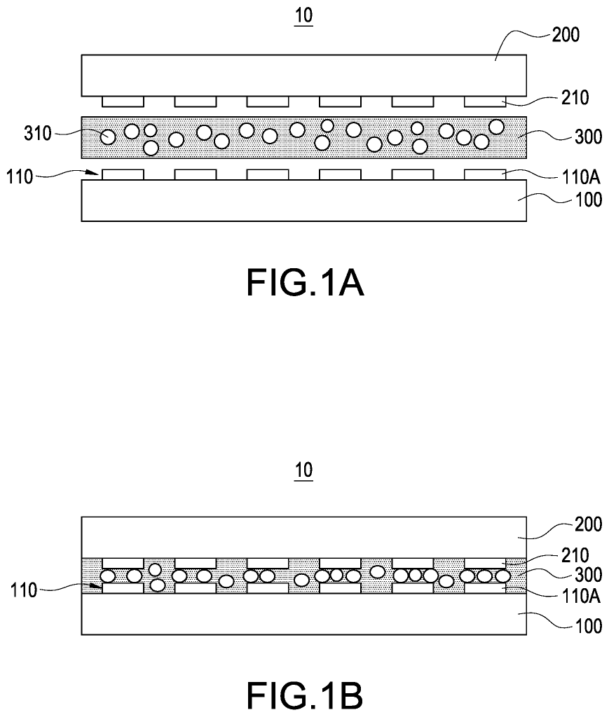

Please refer to FIG. 1A, this figure shows the circuit structure 10 according to a comparative example of the present invention. The circuit structure 10 includes a first substrate 100, a second substrate 200 and a conductive adhesive layer 300 between the first substrate 100 and the second substrate 200. The circuit structure 10 includes a first conductive layer 110 arranged on the first substrate 100 and including a plurality of connection electrodes 110A. The first conductive layer 110 is arranged on a planar surface of the first substrate 100 (for example, the upper planar surface of the first substrate 100 shown in FIG. 1A). Even not clearly shown in FIG. 1A, the plurality of connection electrodes 110A are arranged in rows (or columns) on the planar surface of the first substrate 100. The circuit structure 10 further includes a plurality of conductive pads 210 arranged on a planar surface of the second substrate 200. The plurality of conductive pads 210 are arranged in rows (or columns) on the planar surface of the second substrate 200. Moreover, each conductive pad 210 is corresponding to a connection electrode 110A of the first substrate 100. The conductive adhesive layer 300 can be, for example, an anisotropic conductive adhesive layer, and contains a plurality of conductive particles 310 therein.

Please refer to FIG. 1B, after the connection electrode 110A of the first substrate 100 and the conductive pad 210 of the second substrate 200 opposite to the corresponding connection electrode 110A are heated and pressed, the adhesive layer 300 between the connection electrode 110A and the conductive pad 210 becomes thinned to increase the density of the conductive particles 310 between the connection electrode 110A and the conductive pad 210, thus achieve the electric connection between the connection electrode 110A and the corresponding conductive pad 210.

Please refer to FIGS. 1C and 1D, which are partially enlarged views for showing more detail after the substrates shown in FIG. 1B are pressed. As shown in those figures, an insulating region 120 is usually arranged on a portion of the first substrate 100 and the location of the portion is corresponding to the edge of the second substrate 200 to define a boundary. For example, the insulating region 120 is arranged on the connection electrode 110A corresponding to the edge of the second substrate 200. The connection electrode 110A under the insulating region 120 tends to be broken (such as the break-prone region 114 shown in FIG. 1D) after the connection electrode 110A of the first substrate 100 and the conductive pad 210 of the second substrate 200 opposite to the corresponding connection electrode 110A are heated and pressed, resulting in defective products.

The inventors of the present invention have conducted extensive research and find that the reason accounting for the fracture of the connection electrode 110A is due to insufficient support of the first substrate 100 for the connection electrode 110A. The problem becomes worsen when the first substrate 100 is a flexible substrate, which cannot provide sufficient support for the connecting electrode 110A and may cause more possible fracture of the connecting electrode 110A. Besides, an insulating layer (such as a silicon carbide layer) is usually arranged under the connecting electrodes 110A. The insulating layer has poor ductility and tends to be broken after pressing. As a result, fracture of the connecting electrodes 110A is more likely to occur. The inventors of the present invention have conducted repeated experiments for various designs and propose below embodiments to solve the above problems.

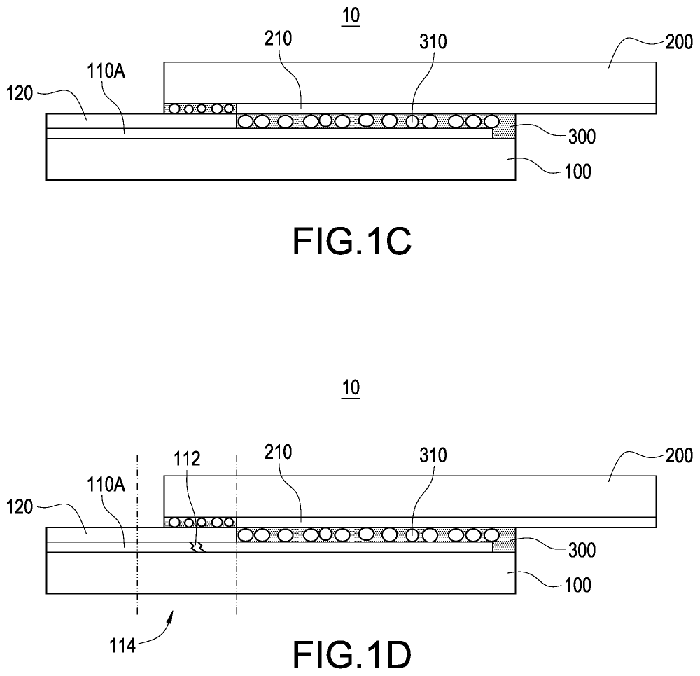

Please refer to FIG. 2, this figure shows a side view of a circuit structure 10 for hot-press bonding according to an embodiment of the present invention. As shown in this figure, the circuit structure 10 of the present invention includes a first substrate 100, a second substrate 200 and a conductive adhesive layer 300 between the first substrate 100 and the second substrate 200. The circuit structure 10 further includes a first conductive layer 110 arranged on the first substrate 100 and including a plurality of connection electrodes 110A. The first conductive layer 110 is arranged on a planar surface of the first substrate 100 (for example, the upper planar surface of the first substrate 100 shown in FIG. 2). Even not clearly shown in FIG. 2, the plurality of connection electrodes 110A are arranged in rows (or columns) on the planar surface of the first substrate 100. The circuit structure 10 further includes a second conductive layer 140 including a plurality of backup electrodes 142. Each of the backup electrodes 142 is corresponding to a connection electrode 110A of the first conductive layer 110. The above-mentioned “corresponding” means there is at least partial overlap between the backup electrode 142 and the corresponding one of the connection electrodes 110A when the circuit structure 10 is viewed from the projection direction. The circuit structure 10 further includes an insulating layer 150 arranged between the first conductive layer 110 and the second conductive layer 140. Namely, the insulating layer 150 is arranged between each backup electrode 142 and the corresponding connection electrode 110A thereof. A plurality of conductive vias 154 is provided in the insulating layer 150. Namely, a plurality of conductive vias 154 is arranged between each backup electrode 142 and the corresponding connection electrode 110A thereof. The plurality of conductive vias 154 penetrate the insulating layer 150 and provide a plurality of current-conduction paths between each of the backup electrodes 142 and a corresponding connection electrode 110A thereof. Therefore, the conductive vias 154 can provide backup conduction path even when the connection electrode 110A is broken due to external force in hot-pressing process, and enhance the reliability of electrical connections and process yield. In this embodiment, the first substrate 100 is, for example, a rigid substrate, such as a glass substrate; or a flexible substrate, such as a PI (Polyimide) substrate. The second conductive layer 140 is, for example, a metal conductive layer, and the metal is, for example, copper, aluminum, molybdenum, or silver. The first conductive layer 110 is, for example, a transparent conductive layer, such as an ITO (indium tin oxide) layer. Alternatively, the first conductive layer 110 is, for example, a metal conductive layer, and the metal can be copper, aluminum, molybdenum, or silver. The second substrate 200 is, for example, a flexible polymer substrate.

Moreover, the circuit structure 10 further includes a plurality of conductive pads 210 arranged on a planar surface of the second substrate 200. The plurality of conductive pads 210 are arranged in rows (or columns) on the planar surface of the second substrate 200. Each conductive pad 210 is corresponding to a connection electrode 110A of the first substrate 100. The conductive adhesive layer 300 can be, for example, an anisotropic conductive adhesive layer, and contains a plurality of conductive particles 310 therein. The conductive adhesive layer 300 bonds the first substrate 100 with the second substrate 200 when the conductive adhesive layer 300 is heated and pressed.

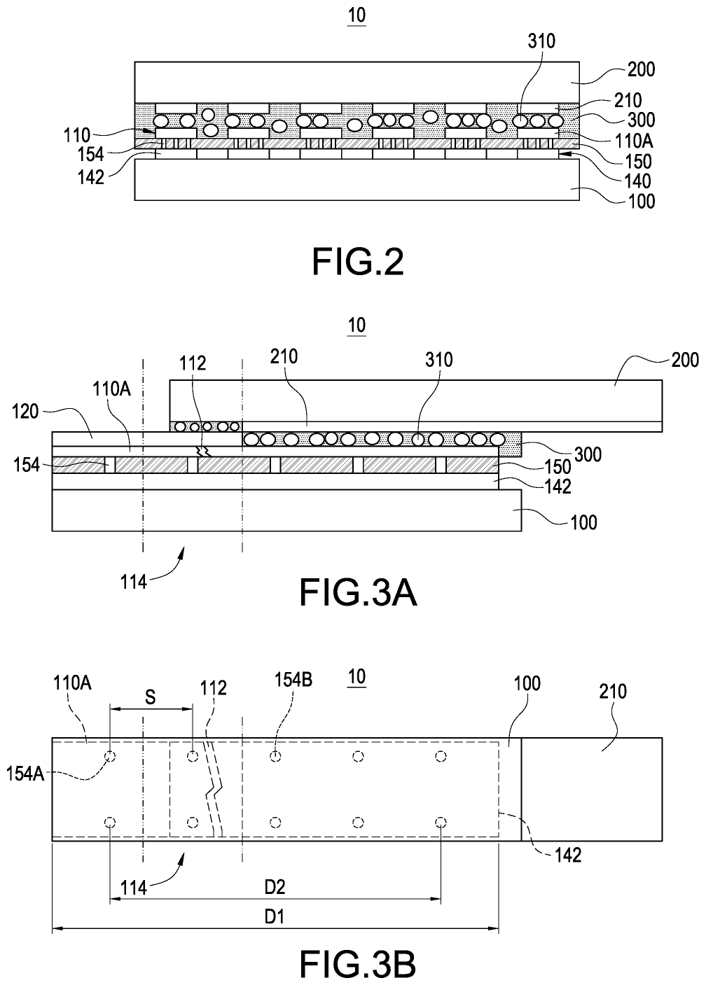

Please refer to FIG. 3A, this figure shows a partial side view of the circuit structure for hot-press bonding according to an embodiment of the present invention. Please also refer to FIG. 3B, this figure shows a top view corresponding to FIG. 3A. The effects and advantages of the present invention can be more clearly manifested in view of above two figures. As shown in FIG. 3A, when the connection electrode 110A is subjected to external force (for example, the force exerted during hot-press bonding process) and has a fracture 112, the right part of the connection electrode 110A and the left part of the connection electrode 110A will be disconnected from each other due to the fracture 112. The electrical signal sent from the conductive pad 210 shown on top portion of FIG. 3A can be conducted to the right part of the connection electrode 110A through the conductive adhesive layer 300 therebetween. However, the electrical signal cannot be sent from the right part of the connection electrode 110A to the left part of the connection electrode 110A due to the fracture 112 in related-art circuit structure. Accordingly, the electrical signal cannot be sent to the next device. For example, the second substrate 200 can be a substrate for mounting a fingerprint sensor, while the fingerprint sensing signal sensed by the fingerprint sensor is transmitted to the first substrate 100 through the second substrate 200. The fingerprint sensing signal is then sent to a processing unit (not shown) on the first substrate 100 to perform further processing. The fingerprint sensing signal cannot be correctly sent to the processing unit for further processing due to the fracture 112. As a result, the electronic device using the fingerprint sensor will malfunction after packaging, this renders the electronic device be a defective product and the yield is reduced.

As shown in FIGS. 3A and 3B, according to the circuit structure 10 for hot-press bonding of the present invention, the left part of the connection electrode 110A can be electrically connected to the backup electrode 142 through the conductive vias 154A, the right part of the connection electrode 110A can also be electrically connected to the backup electrode 142 through the conductive via 154B, even fracture 112 is present in the connection electrode 110A. By above connection scheme, the left part and the right part of the connection electrode 110A can be electrically connected to the backup electrode 142 through the conductive vias 154A and the conductive vias 154B. In other word, the conductive via 154 in the insulating layer 150 and the backup electrode 142 may provide electric connection path between the left part and the right part of the connection electrode 110A even though the left part and the right part of the connection electrode 110A are separate by the fracture 112. The present invention provides backup connection path to enhance reliability of electric connection and yield even though the connection electrode 110A has fracture 112.

In the above-mentioned embodiment, as shown in FIG. 3B, the plurality of conductive vias 154 is disposed at positions corresponding to two long sides of each connecting electrode 110A. In addition, the extending length D2 of the plurality of conductive vias 154 is more than 70% of the length D1 of the connection electrode 110A, so as to increase the number of connection points with which the connection electrode 110A can be electrically connected to the backup electrode 142. According to an embodiment of the present invention, the arrangement of the conductive vias 154 is corresponding to the central portion of the connection electrode 110A and extends uniformly toward two short sides of the connection electrode 110A from the central portion of the connection electrode 110A. Moreover, as shown in FIG. 3B, the separation S between two adjacent conductive vias 154 is not greater than twice the diameter of the conductive vias 154. The aforementioned separation S may be the distance between the centers of two adjacent conductive vias 154, or the distance between the boundaries of two adjacent conductive vias 154. However, the above descriptions are only feasible embodiments of the present invention, and are not intended to limit the scope of the present invention.

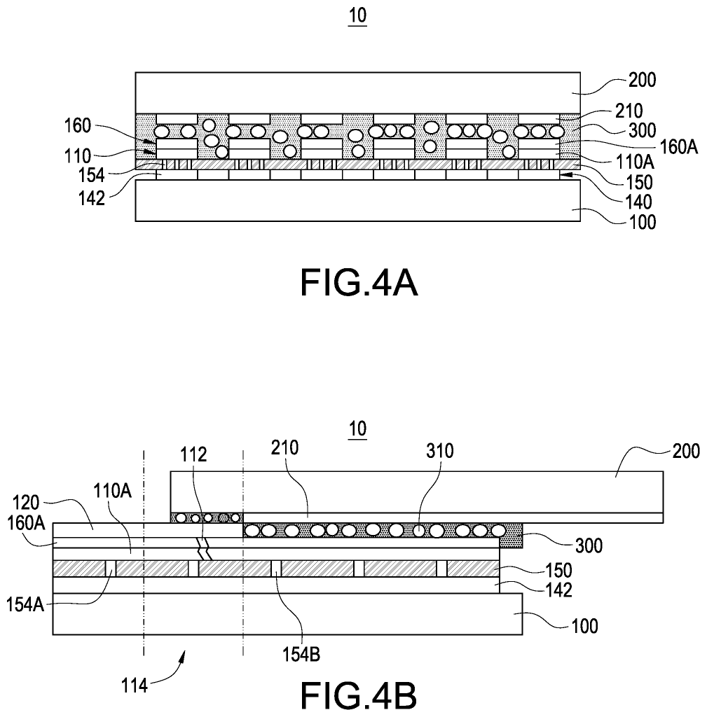

Please refer to FIG. 4A, this figure shows a side view of a circuit structure 10 for hot-press bonding according to another embodiment of the present invention. Please also refer to FIG. 4B, this figure shows a partial side view of a circuit structure for hot-press bonding according to another embodiment of the present invention. As shown in these figures, the circuit structure 10 of the present invention also includes a first substrate 100, a second substrate 200 and a conductive adhesive layer 300 between the first substrate 100 and the second substrate 200. The circuit structure 10 further includes a first conductive layer 110 arranged on the first substrate 100 and including a plurality of connection electrodes 110A. The first conductive layer 110 is arranged on a planar surface of the first substrate 100 (for example, the upper planar surface of the first substrate 100 shown in FIG. 2). Even not clearly shown in FIG. 4A, the plurality of connection electrodes 110A are arranged in rows (or columns) on the planar surface of the first substrate 100. The circuit structure 10 further includes a second conductive layer 140 including a plurality of backup electrodes 142. Each of the backup electrodes 142 is corresponding to a connection electrode 110A of the first conductive layer 110. The circuit structure 10 further includes an insulating layer 150 arranged between the first conductive layer 110 and the second conductive layer 140. Namely, the insulating layer 150 is arranged between each backup electrode 142 and the corresponding connection electrode 110A thereof.

A plurality of conductive vias 154 is provided in the insulating layer 150. Namely, a plurality of conductive vias 154 is arranged between each backup electrode 142 and the corresponding connection electrode 110A thereof. The plurality of conductive vias 154 penetrate the insulating layer 150 and provide a plurality of current-conduction paths between each of the backup electrodes 142 and a corresponding connection electrode 110A thereof. Therefore, the conductive vias 154 can provide backup conduction path even when the connection electrode 110A is broken due to external force in hot-press bonding process, and enhance the reliability of electrical connections and process yield. In this embodiment, the first substrate 100 is, for example, a rigid substrate, such as a glass substrate; or a flexible substrate, such as a PI substrate. The second conductive layer 140 is, for example, a metal conductive layer, and the metal is, for example, copper, aluminum, molybdenum, or silver. The first conductive layer 110 is, for example, a transparent conductive layer, such as an ITO layer. Alternatively, the first conductive layer 110 is, for example, a metal conductive layer, and the metal can be copper, aluminum, molybdenum, or silver. The second substrate 200 is, for example, a flexible polymer substrate

Besides, the circuit structure 10 further includes a plurality of conductive pads 210 arranged on a planar surface of the second substrate 200. The plurality of conductive pads 210 are arranged in rows (or columns) on the planar surface of the second substrate 200. Each conductive pad 210 is corresponding to a connection electrode 110A of the first substrate 100. The conductive adhesive layer 300 can be, for example, an anisotropic conductive adhesive layer, and contains a plurality of conductive particles 310 therein. The conductive adhesive layer 300 bonds the first substrate 100 with the second substrate 200 when the conductive adhesive layer 300 is heated and pressed.

The embodiment shown in FIGS. 4A and 4B is different with the embodiment shown in FIGS. 2, 3A and 3B mainly in that the circuit structure 10 shown in FIGS. 4A and 4B further includes a transparent conductive layer 160 between the first conductive layer 110 and the conductive adhesive layer 300. The transparent conductive layer 160 includes a plurality of transparent connection electrodes 160A. Each of the transparent connection electrodes 160A is corresponding to and electrically connected to one connection electrode 110A of the first conductive layer 110. By providing the transparent conductive layer 160, the connection electrode 110A has better affinity with the conductive adhesive layer 300 and the connection electrode 110A has additional backup conduction path.

Similarly, as shown in FIGS. 4A and 4B, according to the circuit structure 10 for hot-press bonding of the present invention, the left part of the connection electrode 110A can be electrically connected to the backup electrode 142 through the conductive vias 154A, the right part of the connection electrode 110A can also be electrically connected to the backup electrode 142 through the conductive via 154B, even fracture 112 is present in the connection electrode 110A. By above connection scheme, the left part and the right part of the connection electrode 110A can be electrically connected to the backup electrode 142 through the conductive vias 154A and the conductive vias 154B. In other word, the conductive via 154 in the insulating layer 150 and the backup electrode 142 may provide electric connection between the left part and the right part of the connection electrode 110A even though the left part and the right part of the connection electrode 110A are separate by the fracture 112. The present invention provides backup connection path to enhance reliability of electric connection and yield even though the connection electrode 110A has fracture 112.

Similarly, in the above-mentioned embodiment shown in FIGS. 4A and 4B, the plurality of conductive vias 154 is disposed at positions corresponding to two long sides of each connecting electrode 110A. In addition, the extending length D2 of the plurality of conductive vias 154 is more than 70% of the length D1 of the connection electrode 110A, so as to increase the number of connection points with which the connection electrode 110A can be electrically connected to the backup electrode 142. According to an embodiment of the present invention, the arrangement of the conductive vias 154 is corresponding to the central portion of the connection electrode 110A and extends uniformly toward two short sides of the connection electrode 110A from the central portion of the connection electrode 110A. Moreover, as shown in FIG. 3B, the separation S between two adjacent conductive vias 154 is not greater than twice the diameter of the conductive vias 154. The aforementioned separation S may be the distance between the centers of two adjacent conductive vias 154, or the distance between the boundaries of two adjacent conductive vias 154. However, the above descriptions are only feasible embodiments of the present invention, and are not intended to limit the scope of the present invention

While this invention has been described by means of specific embodiments, numerous modifications and variations could be made thereto by those skilled in the art without departing from the scope and spirit of this invention set forth in the claims.

What is claimed is:

1. A circuit structure for hot-press bonding, the circuit structure comprising:
a first substrate;
a first conductive layer comprising a plurality of connection electrodes, the plurality of connection electrodes arranged in rows and arranged on a planar surface of the first substrate;
a second conductive layer comprising a plurality of backup electrodes, each of the backup electrodes corresponding to one of the connection electrodes of the first conductive layer;
an insulating layer arranged between the first conductive layer and the second conductive layer;
a plurality of conductive vias arranged in the insulating layer; wherein multiple of the conductive vias are provided between each of the backup electrodes and a corresponding one of the connection electrodes such that multiple of the conductive vias provide current conduction paths between each of the backup electrodes and the corresponding one of the connection electrodes;
a second substrate;
a plurality of conductive pads arranged in a row and arranged on a planar surface of the second substrate, each of the conductive pads being corresponding to one of the connecting electrodes of the first substrate; and
a conductive adhesive layer arranged between the plurality of connection electrodes of the first substrate and the plurality of conductive pads of the second substrate such that each of the connection electrodes is electrically connected to a corresponding one of the conductive pads.

2. The circuit structure in claim 1, wherein the first substrate is a rigid substrate or a flexible substrate.

3. The circuit structure in claim 1, wherein the second conductive layer is a metal conductive layer.

4. The circuit structure in claim 1, wherein the first conductive layer is a transparent conductive layer.

5. The circuit structure in claim 1, wherein the first conductive layer is a metal conductive layer.

6. The circuit structure in claim 1, further comprising a transparent conductive layer arranged on the first conductive layer, wherein the transparent conductive layer comprises a plurality of transparent connection electrodes, each of the transparent connection electrodes is corresponding and electrically connected to one of the connecting electrodes of the first conductive layer.

7. The circuit structure in claim 1, wherein the conductive vias are arranged along two long sides of each of the connecting electrodes.

8. The circuit structure in claim 7, wherein an extended length of the conductive vias is more than 70% of a length of the connecting electrode, and the separation between two adjacent conductive vias is not greater than twice a diameter of the conductive vias.

9. The circuit structure in claim 1, wherein the second substrate is a flexible polymer substrate.

10. The circuit structure in claim 1, wherein the conductive adhesive layer is anisotropic conductive film (ACF) layer.

11. The circuit structure in claim 1, wherein the conductive adhesive layer is configured to bond the first substrate and the second substrate after heating and pressing.
